(19) United States
(12) Patent Application Publication
(10) Pub. No.: US 2025/0095971 A1
(43) Pub. Date: Mar. 20, 2025

(54) PLASMA PROCESSING APPARATUS AND METHOD FOR FABRICATING SEMICONDUCTOR DEVICE USING THE SAME

(71) Applicant: SAMSUNG ELECTRONICS CO. LTD., Suwon-si (KR)

(72) Inventors: Ji Mo LEE, Suwon-si (KR); kyung-Sun Kim, Suwon-si (KR); Dong Hyeon Na, Suwon-si (KR); Jung Hyun Song, Suwon-si (KR); Myeong Soo Shin, Suwon-si (KR); Seung Bo Shim, Suwon-si (KR); Kui Hyun Yoon, Suwon-si (KR); Jun Ho Lee, Suwon-si (KR); Woong Jin Cheon, Suwon-si (KR); Dong Seok Han, Suwon-si (KR)

(73) Assignee: SAMSUNG ELECTRONICS CO., LTD., Suwon-si (KR)

(21) Appl. No.: 18/640,181

(22) Filed: Apr. 19, 2024

(30) Foreign Application Priority Data
Sep. 20, 2023 (KR) 10-2023-0125479

(51) Int. Cl. H01J 37/32

(52) U.S. Cl. CPC H01J 37/3266; H01J 37/32146; H01J 2237/334

(57) ABSTRACT

A plasma processing apparatus includes: a plasma chamber; a radio frequency (RF) power supply configured to generate plasma in the plasma chamber; an electromagnet configure to apply a magnetic field to the plasma; and a pulse current generator configured to provide a pulse current to the electromagnet, wherein each period of the pulse current includes a first section and a second section subsequent to the first section, and the pulse current generator is further configured to: provide, at the first section, the pulse current to the electromagnet in a first direction to generate the magnetic field, and provide, at the second section, the pulse current to the electromagnet in a second direction opposite to the first direction to reduce intensity of the magnetic field generated at the first section.

### CROSS-REFERENCE TO RELATED APPLICATION

This application is based on and claims priority under 35 U.S.C. § 119 to Korean Patent Application No. 10-2023-0125479, filed on Sep. 20, 2023, in the Korean Intellectual Property Office, the disclosure of which is incorporated by reference herein.

### BACKGROUND

The present disclosure relates to a plasma processing apparatus and a method for fabricating a semiconductor device using the same, and more particularly, to a plasma processing apparatus in which plasma distribution is controlled using a magnetic field, and a method for fabricating a semiconductor device using the same.

Semiconductor devices can be formed by various semiconductor fabricating processes such as an etching process, a deposition process, an ashing process and a cleaning process. In particular, plasma processes that accelerate a desired chemical reaction (e.g., deposition or etching) using plasma have been recently used in various ways.

As semiconductor devices become increasingly highly integrated, technologies capable of controlling plasma more precisely are required. For example, technologies for using a magnetic field to control plasma distribution are being studied.

### SUMMARY

One or more example embodiments provide a plasma processing apparatus that may be easy for process optimization.

Further, one or more example embodiments provide a method for fabricating a semiconductor device using a plasma processing apparatus that may be easy for process optimization.

The aspects of the disclosure are not limited to those mentioned above and additional aspects of the disclosure, which are not mentioned herein, will be clearly understood by those skilled in the art from the following description of the disclosure.

According to an aspect of an example embodiment, a plasma processing apparatus includes: a plasma chamber; a radio frequency (RF) power supply configured to generate plasma in the plasma chamber; an electromagnet configured to apply a magnetic field to the plasma; and a pulse current generator configured to provide a pulse current to the electromagnet, wherein each period of the pulse current includes a first section and a second section subsequent to the first section, and the pulse current generator is further configured to: provide, at the first section, the pulse current to the electromagnet in a first direction to generate the magnetic field, and provide, at the second section, the pulse current to the electromagnet in a second direction opposite to the first direction to reduce intensity of the magnetic field generated at the first section.

According to an aspect of an example embodiment, a plasma processing apparatus includes: a plasma chamber; an radio frequency (RF) power supply configured to generate plasma in the plasma chamber; an electromagnet configured to apply a magnetic field to the plasma; and a pulse current generator configured to provide a direct current (DC) pulse signal to the electromagnet, wherein each period of the DC pulse signal includes a first section and a second section subsequent to the first section, and the pulse current generator is further configured to: provide, at the first section, the DC pulse signal at a first level having a first polarity, and provide, at the second section, the DC pulse signal at a second level having a second polarity opposite to the first polarity.

According to an aspect of an example embodiment, a plasma processing apparatus includes: a chamber body; a stage, on which a substrate is mounted, in the chamber body; a distribution plate spraying a process gas into the chamber body; a radio frequency (RF) power supply configured to generate plasma from the process gas; a direct current (DC) power supply configured to provide a DC signal; a timing controller configured to generate a DC pulse signal from the DC signal; and an electromagnet in the distribution plate, the electromagnet being configured to generate a magnetic field by using the DC pulse signal, wherein each period of the DC pulse signal includes a first section and a second section subsequent to the first section, at the first section, the DC pulse signal is provided at a first level having a first polarity, and at the second section, the DC pulse signal is provided at a second level having a second polarity opposite to the first polarity.

### BRIEF DESCRIPTION OF THE DRAWINGS

The above and other aspects and features of the present disclosure will become more apparent by describing in detail example embodiments thereof with reference to the attached drawings, in which:

FIG. 1 illustrates a plasma processing apparatus according to one or more embodiments;

FIG. 2 is a plan view illustrating an electromagnet of the plasma processing apparatus of FIG. 1;

FIG. 3 is a timing view illustrating a pulse current of the plasma processing apparatus of FIG. 1;

FIG. 4 is a timing view illustrating an effect of a plasma processing apparatus according to one or more embodiments;

FIGS. 5 and 6 are various timing views illustrating a pulse current of a plasma processing apparatus according to one or more embodiments;

FIG. 7 illustrates a plasma processing apparatus according to one or more embodiments;

FIG. 8 is a plan view illustrating an electromagnet of the plasma processing apparatus of FIG. 7;

FIG. 9 is a timing view illustrating a pulse current of the plasma processing apparatus of FIG. 7;

FIG. 10 illustrates a plasma processing apparatus according to one or more embodiments;

FIG. 11 is a plan view illustrating an electromagnet of the plasma processing apparatus of FIG. 10;

FIGS. 12, 13, and 14 are timing views illustrating a pulse current of the plasma processing apparatus of FIG. 10;

FIGS. 15, 16, and 17 illustrate a plasma processing apparatus according to embodiments;

FIG. 18 illustrate a plasma processing apparatus according to one or more embodiments;

FIG. 19 is an enlarged view illustrating an area Z1 of FIG. 18;

FIG. 20 illustrates a plasma processing apparatus according to one or more embodiments;

FIG. 21 is an enlarged view illustrating an area Z2 of FIG. 20; and

FIGS. 22 and 23 illustrate a method for fabricating a semiconductor device according to embodiments.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or.” The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

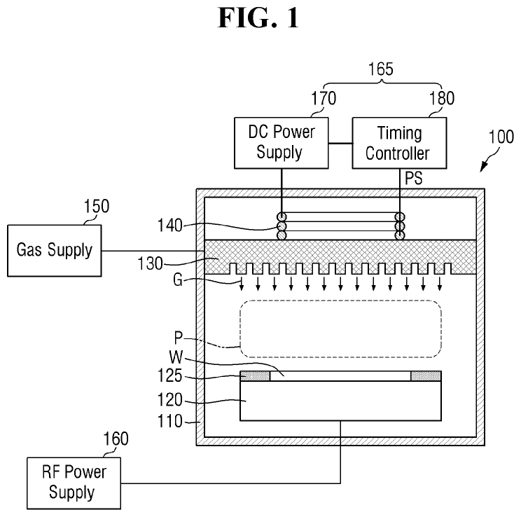

Hereinafter, a plasma processing apparatus according to exemplary embodiments will be described with reference to FIGS. 1 to 3.

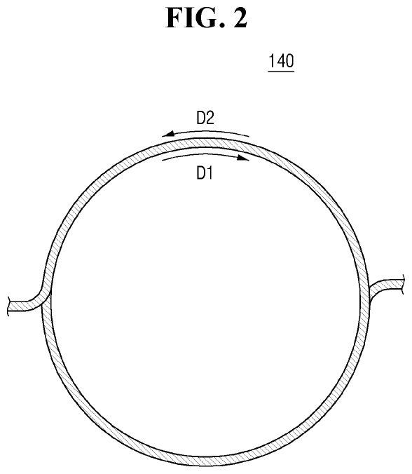

FIG. 1 illustrates a plasma processing apparatus according to one or more embodiments. FIG. 2 is a plan view illustrating an electromagnet of the plasma processing apparatus of FIG. 1.

Referring to FIGS. 1 and 2, the plasma processing apparatus according to one or more embodiments may include a plasma chamber 100, a distribution plate 130, an electromagnet 140, a gas supply 150, an RF power supply 160, and a pulse current generator 165. In an embodiment, the pulse current generator 165 may include a direct current (DC) power supply 170 and a timing controller 180.

The plasma chamber 100 may provide an area for processing a substrate W by using a plasma process. The substrate W may include a wafer and/or at least one material layer on the wafer as targets of a process performed in the plasma chamber 100. The process on the substrate W may correspond to an etching process, a deposition process, an ashing process, a cleaning process, or other processes. In an embodiment, the plasma chamber 100 may include a chamber body 110, a stage 120, and a focus ring 125.

The chamber body 110 generates plasma P and provides an internal area for processing the substrate W. The chamber body 110 may separate the internal area from the outside. The chamber body 110 may be a clean room facility capable of controlling pressure and temperature with high precision. An overall outer structure of the chamber body 110 may correspond to, for example, a cylindrical shape, an oval cylinder shape, a polygonal column shape, or other shapes. The chamber body 110 may include, for example, a metal material such as aluminum (Al), but is not limited thereto. In one or more embodiments, the chamber body 110 may be maintained in a grounded state to block noise from the outside, which may occur during a plasma process.

The stage 120 may be disposed in the chamber body 110. The substrate W may be mounted on the stage 120 and supported by the stage 120. The stage 120 may include, for example, an electrostatic chuck (ESC), but is not limited thereto.

The focus ring 125 may be disposed on the stage 120. The focus ring 125 may be in the form of a ring surrounding the substrate W disposed on the stage 120. The focus ring 125 may fix the substrate W disposed on the stage 120. In addition, the focus ring 125 may improve efficiency of the plasma process by collecting the plasma P toward a surface of the substrate W. The focus ring 125 may include, for example, silicon (Si), but is not limited thereto.

The gas supply 150 may provide a process gas G toward the plasma chamber 100. The process gas G may be a source gas for generating the plasma P in the plasma chamber 100.

In the plasma chamber 100, the distribution plate 130 may be connected to the gas supply 150. The distribution plate 130 may receive the process gas G from the gas supply 150 and distribute the process gas G onto the substrate W. For example, the process gas G provided from the gas supply 150 may be sprayed onto the substrate W through a gas hole of the distribution plate 130. In one or more embodiments, the distribution plate 130 may include an ion filter. The process gas G provided from the gas supply 150 may be filtered through the ion filter and distributed onto the substrate W.

The RF power supply 160 may provide a radio frequency (RF) power source signal for generating or controlling the plasma P. For example, the stage 120 may include a first electrode, and the distribution plate 130 may include a second electrode facing the first electrode. The first electrode of the stage 120 may be connected to the RF power supply 160, and the second electrode of the distribution plate 130 may be grounded. When the process gas G is supplied into the plasma chamber 100 through the distribution plate 130, the RF power supply 160 may supply the RF power to the first electrode of the stage 120. Therefore, the plasma P may be generated between the first electrode of the stage 120 and the second electrode of the distribution plate 130. The RF power source signal for generating the plasma P may have a frequency (e.g., about 60 MHz) ranging from several MHz to several hundreds of MHz, but the frequency is not limited thereto.

A capacitively coupled plasma (CCP) method is described as an example for generating the plasma P. Embodiments of the disclosure are not limited thereto. In some other embodiments, the plasma P may be generated in an inductively coupled plasma (ICP) manner. In some other embodiments, the plasma P may be generated by the CCP manner and the ICP manner in combination.

In one or more embodiments, the RF power source signal provided from the RF power supply 160 may have a macro-pulse. For example, at an ‘ON’ section of the macro-pulse, the RF power supply 160 may generate the plasma P by providing the RF power source signal having a micro-pulse of about 60 MHz. In addition, at an ‘OFF’ section of the macro-pulse, the RF power supply 160 may be turned off so that it may not generate the plasma P. The macro-pulse may have a frequency (e.g., about 1 kHz) ranging from several kHz to several tens of kHz, but the frequency is not limited thereto.

The electromagnet 140 may generate a magnetic field when a current flows in the form of a coil. The magnetic field generated by the electromagnet 140 may be applied to the plasma P to control distribution of the plasma P. The electromagnet 140 may include solenoid, but is not limited thereto.

In one or more embodiments, the magnetic field generated from the electromagnet 140 may have a direction crossing an upper surface of the substrate W. For example, a central axis of the coil constituting the electromagnet 140 may cross (e.g., be perpendicular to) the upper surface of the substrate W. Therefore, the magnetic field generated by the electromagnet 140 may be applied to the plasma P in a direction (e.g., vertical direction) crossing the upper surface of the substrate W.

In one or more embodiments, the electromagnet 140 may apply a magnetic field to the plasma P from a location above the plasma P. For example, the electromagnet 140 may be disposed on an upper surface of the distribution plate 130 in the chamber body 110, but this is only exemplary. In one or more embodiments, the electromagnet 140 may be disposed on a lower surface of the distribution plate 130. Alternatively, the electromagnet 140 may be disposed outside the chamber body 110.

The pulse current generator 165 may be connected to the electromagnet 140. For example, the pulse current generator 165 may form a closed circuit with the electromagnet 140. The pulse current generator 165 may generate a pulse current PS (shown in FIG. 1) at which an ‘ON’ section and an ‘OFF’ section are repeated. The electromagnet 140 may receive the pulse current PS from the pulse current generator 165, and may form a ‘magnetic field’ that varies with respect to time. Hereinafter, the magnetic field may be referred to as a ‘time varying magnetic field.’

In one or more embodiments, the pulse current generator 165 may control the pulse current PS to flow in a predetermined direction along the electromagnet 140 at the ‘ON’ section of the pulse current PS. For example, as shown in FIG. 2, the pulse current PS may be controlled to flow in a first direction D1, which is a clockwise direction, along the electromagnet 140 or to flow in a second direction D2, which is a counterclockwise direction, along the electromagnet 140.

In one or more embodiments, a frequency of the pulse current PS may be 100 Hz or higher. That is, the period of the pulse current PS may be 10 ms or less. In one or more embodiments, the frequency of the pulse current PS may be 1 kHz or higher. That is, the period of the pulse current PS may be 1 ms or less.

In one or more embodiments, the pulse current PS may be provided in response to (or based on) the macro-pulse of the RF power source signal provided from the RF power supply 160. For example, a first frequency of the macro-pulse and a second frequency of the pulse current PS may be equally about 1 kHz. The pulse current PS may be synchronized or desynchronized with the macro-pulse of the RF power source signal. Alternatively, the pulse current PS may have a phase shifted from the macro-pulse of the RF power source signal.

In one or more embodiments, the pulse current PS may include a direct current (DC) pulse signal. For example, the pulse current generator 165 may include the DC power supply 170 and the timing controller 180.

The DC power supply 170 may provide a DC signal. The timing controller 180 may be connected to the DC power supply 170. The timing controller 180 may convert the DC signal provided from the DC power supply 170 into a DC pulse signal. For example, the timing controller 180 may generate the DC pulse signal by controlling the ‘ON’ section and the ‘OFF’ section of the DC signal.

The DC power supply 170 and the timing controller 180 may form a closed circuit with the electromagnet 140. For example, the DC power supply 170 may be connected to one end of the electromagnet 140, and the timing controller 180 may be connected to the other end of the electromagnet 140.

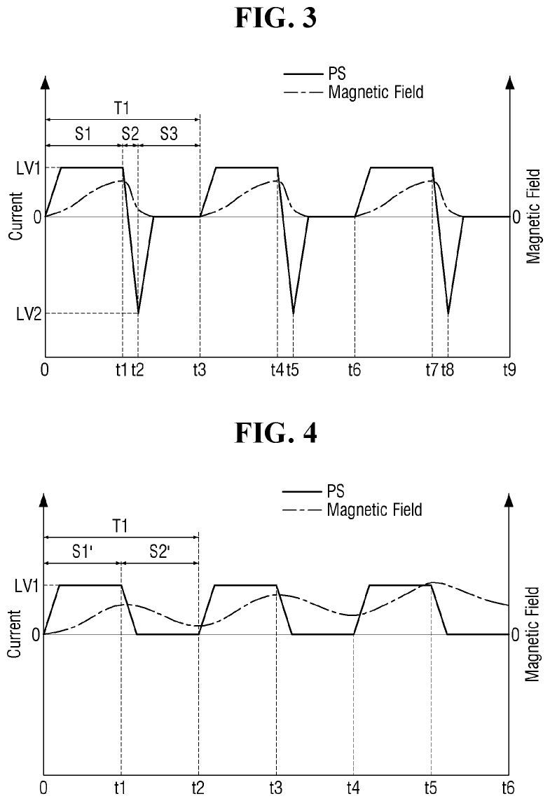

FIG. 3 is a timing view illustrating a pulse current of the plasma processing apparatus of FIG. 1. FIG. 4 is a timing view illustrating an effect of a plasma processing apparatus according to one or more embodiments. In FIGS. 3 and 4, a solid line represents a current applied to the electromagnet 140 in accordance with the pulse current PS, and a dashed dotted line represents a magnetic field generated by the electromagnet 140 in accordance with the pulse current PS.

Referring to FIGS. 1 to 4, in the plasma processing apparatus according to one or more embodiments, each period T1 of the pulse current PS may include a first section S1, a second section S2 subsequent to the first section S1, and a third section S3 subsequent to the second section S2.

For example, at the first section T1 of the pulse current PS, the first section S1 may be defined from a start time point 0 to a time point t1, the second section S2 may be defined from the time point t1 to a time point t2, and the third section S3 may be defined from the time point t2 to a time point t3. As the pulse current PS continues, the first section S1, the second section S2 and the third section S3 may be periodically repeated.

At the first section S1, the pulse current PS may be provided at a first level LV1 having a first polarity (e.g., +). For example, the pulse current PS may be provided in a first direction D1 (e.g., clockwise direction in FIG. 2). Therefore, as shown in FIG. 3, a current applied to the electromagnet 140 at the first section S1 (e.g., 0 to t1, t3 to t4 or t6 to t7) may reach the first level LV1, and a magnetic field may be generated from the electromagnet 140 toward a predetermined direction (e.g., in a direction toward the plasma P or away from the plasma P).

At the second section S2, the pulse current PS may be provided at a second level LV2 having a second polarity (e.g., −) opposite to the first polarity. For example, the pulse current PS may be provided in a second direction D2 (e.g., counterclockwise direction in FIG. 2) opposite to the first direction D1. Therefore, as shown in FIG. 3, the current applied to the electromagnet 140 at the second section S2 (e.g., t1 to t2, t4 to t5 or t7 to t8) may reach the second level LV2, and intensity of the magnetic field generated at the first section S1 may be quickly reduced.

In one or more embodiments, intensity of the magnetic field at an end time point (e.g., t2, t5 or t8) of the second section S2 may be about 10% or less in comparison with intensity of the magnetic field at an end time point (e.g., t1, t4 or t7) of the first section S1. In one or more embodiments, the intensity of the magnetic field at the end time point (e.g., t2, t5 or t8) of the second section S2 may be about 5% or less in comparison with the intensity of the magnetic field at the end time point (e.g., t1, t4 or t7) of the first section S1. In some other embodiments, the intensity of the magnetic field at the end time point (e.g., t2, t5 or t8) of the second section S2 may be about 1% or less in comparison with the intensity of the magnetic field at the end time point (e.g., t1, t4 or t7) of the first section S1.

The third section S3 may be an ‘OFF’ section. Therefore, as shown in FIG. 3, the current applied to the electromagnet 140 at the third section S3 (e.g., t2 to t3, t5 to t6 or t8 to t9) may reach zero (0). In addition, an additional magnetic field may not be generated by the pulse current PS.

A length of the second section S2 and a magnitude of the second level LV2 may be adjusted such that the magnetic field is ‘extinguished’ at the end time point (e.g., t3, t6 or t9) of each period T1 of the pulse current PS. In this case, the term “extinction” (or being extinguished) means that the magnetic field is completely extinguished and the magnetic field has intensity that does not affect distribution of the plasma P. For example, as shown in FIG. 3, at the end time point (e.g., t3, t6 or t9) of each period T1 of the pulse current PS, intensity of the magnetic field generated by the electromagnet 140 may be zero (0).

In one or more embodiments, the length of the second section S2 may be shorter than that of the first section S1, and the magnitude of the second level LV2 (i.e., an absolute value of the second level LV2) may be greater than that of the first level LV1 (i.e., absolute value of the first level LV1). In this case, the magnetic field generated at the first section S1 may be more quickly controlled and ‘extinguished.’

In one or more embodiments, the length of the second section S2 may be less than or equal to about 25% of the length of the first section S1. For example, the length of the second section S2 may be about 10% to about 25% of the length of the first section S1.

In one or more embodiments, the magnitude of the second level LV2 may be about two or more times of the magnitude of the first level LV1. For example, the magnitude of the second level LV2 may be about 2 times to about 5 times of the magnitude of the first level LV1.

As semiconductor devices become increasingly highly integrated, technologies capable of controlling plasma need to be more precise. For example, technologies for using a magnetic field to control plasma distribution are being studied.

As described above, the plasma processing apparatus according to one or more embodiments may control the distribution of the plasma P by forming the time varying magnetic field using the pulse current PS. The time varying magnetic field may improve a control capability for distribution of the plasma P by inducing temporal behavior of the plasma P.

However, when an RF current equal to or greater than about 100 Hz is used as the pulse current for forming the time varying magnetic field, a problem occurs in that the control capability is lost as the time for extinguishing the magnetic field at each period is not obtained. For example, unlike the pulse current PS of FIG. 3, each period T1 of the pulse current PS of FIG. 4 may include only an ‘ON’ section S1′ provided at the first level LV1 and an ‘OFF’ section S2′ subsequent to the ‘ON’ section S1′. At the ‘ON’ section S1′, the pulse current PS may generate a magnetic field of the electromagnet 140. The ‘OFF’ section S2′ may extinguish the magnetic field generated at the ‘ON’ section S1. However, when the pulse current PS of a radio frequency (e.g., about 100 Hz or higher) is applied to the electromagnet 140, the magnetic field generated at the ‘ON’ section S1′ may not be completely extinguished at the ‘OFF’ section S2′. For example, at the end time point (e.g., t2) of the first section t1 of the pulse current PS, the intensity of the magnetic field generated by the electromagnet 140 may remain without being completely extinguished. Therefore, the magnetic field applied to the plasma P at a subsequent period T1 (e.g., t2 to t4) may be different from the magnetic field applied to the plasma P at a preceding period T1 (e.g., 0 to t2), which may degrade a plasma distribution control capability using a time varying magnetic field.

Unlike the time varying magnetic field shown in FIG. 4, the plasma processing apparatus, according to one or more embodiments, may control plasma distribution even with the pulse current PS of the radio frequency by using the second section S2 for applying a current in a direction opposite to the first section S1 subsequently to the first section S1 for forming the magnetic field. In detail, as described above with reference to FIG. 3, since the pulse current PS may have the first polarity (e.g., +) at the first section S1 and may be provided as the second polarity (e.g., −) at the second section S2 subsequent to the first section S1, the intensity of the magnetic field generated at the first section S1 may be quickly controlled and ‘extinguished’ at the second section S2. As a result, a control window may be improved, so that the plasma processing apparatus that is easy for process optimization may be provided.

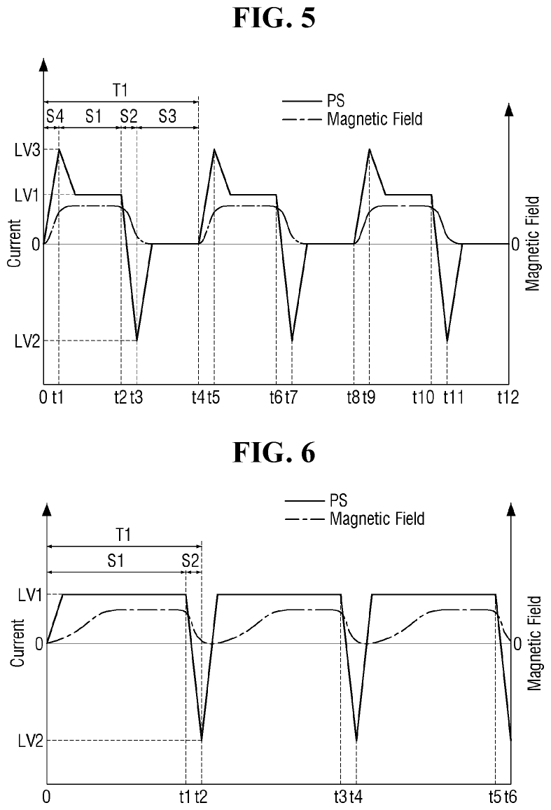

FIGS. 5 and 6 are various timing views illustrating a pulse current of a plasma processing apparatus according to embodiments. Redundant portions of those described above with reference to FIGS. 1 to 4 will be briefly described or omitted.

Referring to FIG. 5, in the plasma processing apparatus according to one or more embodiments, each period T1 of the pulse current PS may further include a fourth section S4 preceding the first section S1.

For example, at the first section t1 of the pulse current PS, the fourth section S4 may be defined from the start time point 0 to the time point t1, the first section S1 may be defined from the time point t1 to the time point t2, the second section S2 may be defined from the time point t2 to the time point t3, and the third section S3 may be defined from the time point t3 to the time point t4. As the pulse current PS continues, the fourth section S4, the first section S1, the second section S2 and the third section S3 may be periodically repeated.

At the fourth section S4, the pulse current PS may be provided at a third level LV3 having the first polarity (e.g., +). For example, the pulse current PS may be provided in the first direction D1 (e.g., clockwise direction in FIG. 2). In addition, at the fourth section S4, the pulse current PS may be provided at the third level LV3 greater than the first level LV1. In this case, as shown in FIG. 5, the magnetic field generated from the electromagnet 140 may reach a predetermined level more quickly, and plasma distribution control capability using the time varying magnetic field may be more improved.

In one or more embodiments, a length of the fourth section S4 may be less than or equal to about 25% of the length of the first section S1. For example, the length of the fourth section S4 may be about 10% to about 25% of the length of the first section S1.

Referring to FIG. 6, in the plasma processing apparatus according to one or more embodiments, each period T1 of the pulse current PS may not include an ‘OFF’ section.

For example, at the first section T1 of the pulse current PS, the first section S1 may be defined from the start time point 0 to the time point t1, and the second section S2 may be defined from the time point t1 to the time point t2. As the pulse current PS continues, the first section S1 and the second section S2 may be periodically repeated.

In one or more embodiments, the length of the second section S2 and the magnitude of the second level LV2 may be adjusted to the extent that the magnetic field is ‘extinguished’ at the end time point (e.g., t2, t4 or t6) of the second section S2. For example, at the end time point (e.g., t3, t6 or t9) of the second section S2, the intensity of the magnetic field generated by the electromagnet 140 may be zero (0).

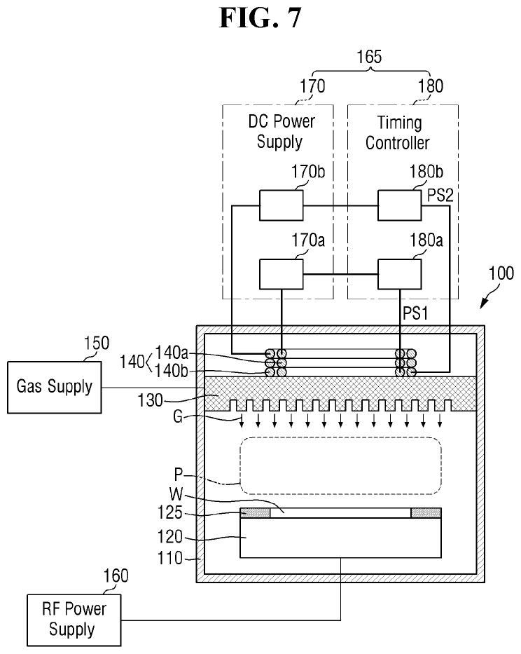

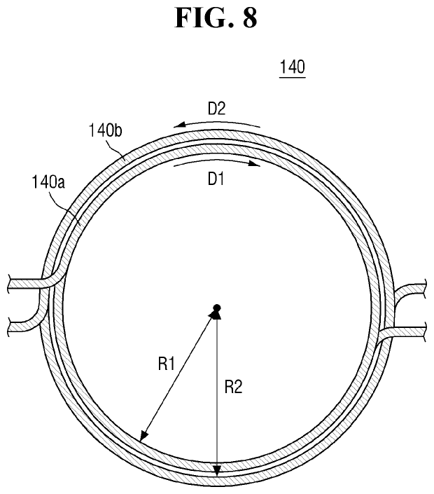

FIG. 7 illustrates a plasma processing apparatus according to one or more embodiments. FIG. 8 is a plan view illustrating an electromagnet of the plasma processing apparatus of FIG. 7. Redundant portions of those described above with reference to FIGS. 1 to 6 will be briefly described or omitted.

Referring to FIGS. 7 and 8, in the plasma processing apparatus according to one or more embodiments, the electromagnet 140 may include a first sub-coil 140a and a second sub-coil 140b.

Each of the first sub-coil 140a and the second sub-coil 140b may generate a magnetic field when a current flows. The magnetic field generated by the first sub-coil 140a and the second sub-coil 140b may be applied to the plasma P to control distribution of the plasma P. Each of the first sub-coil 140a and the second sub-coil 140b may include solenoid, but is not limited thereto.

As shown in FIG. 8, the first sub-coil 140a may have a first radius R1, and the second sub-coil 140b may have a second radius R2 different from the first radius R1. For example, the second radius R2 of the second sub-coil 140b may be greater than the first radius R1 of the first sub-coil 140a. In one or more embodiments, the first sub-coil 140a and the second sub-coil 140b may share the ‘same’ central axis. In the disclosure, the term “same” means that it is not only completely identical but also includes a fine difference that may occur due to a process margin or the like.

In one or more embodiments, the difference between the first radius R1 and the second radius R2 may be about 10% or less with respect to the first radius R1. In this case, the first sub-coil 140a and the second sub-coil 140b may control distribution of the plasma P in substantially the same area.

The pulse current generator 165 may be connected to the first sub-coil 140a and the second sub-coil 140b, respectively. For example, the DC power supply 170 may include a first sub-DC power source 170a and a second sub-DC power source 170b, and the timing controller 180 may include a first sub-timing controller 180a connected to the first sub-DC power source 170a and a second sub-timing controller 180b connected to the second sub-DC power source 170b.

The first sub-timing controller 180a may convert a first DC signal provided from the first sub-DC power source 170a into a first DC pulse signal PS1. The first sub-DC power source 170a and the first sub-timing controller 180a may form a closed circuit with the first sub-coil 140a. Therefore, the first DC pulse signal PS1 may be provided to the first sub-coil 140a.

The second sub-timing controller 180b may convert a second DC signal provided from the second sub-DC power source 170b into a second DC pulse signal PS2. In addition, the second sub-DC power source 170b and the second sub-timing controller 180b may form a closed circuit with the second sub-coil 140b. Therefore, the second DC pulse signal PS2 may be provided to the second sub-coil 140b.

In one or more embodiments, a frequency of the first DC pulse signal PS1 and a frequency of the second DC pulse signal PS2 may be 100 Hz or higher. In one or more embodiments, the frequency of the first DC pulse signal PS1 and the frequency of the second DC pulse signal PS2 may be 1 kHz or higher.

In one or more embodiments, the first DC pulse signal PS1 applied to the first sub-coil 140a and the second DC pulse signal PS2 applied to the second sub-coil 140b may have their respective directions different from each other. For example, as shown in FIG. 8, the first DC pulse signal PS1 may flow in the first direction D1, which is a clockwise direction, along the first sub-coil 140a, and the second DC pulse signal PS2 may flow in the second direction D2, which is a counterclockwise direction, along the second sub-coil 140b.

The electromagnet 140 has been described as including only two sub-coils (the first sub-coil 140a and the second sub-coil 140b), but this is only exemplary, and the electromagnet 140 may include three or more sub-coils as necessary.

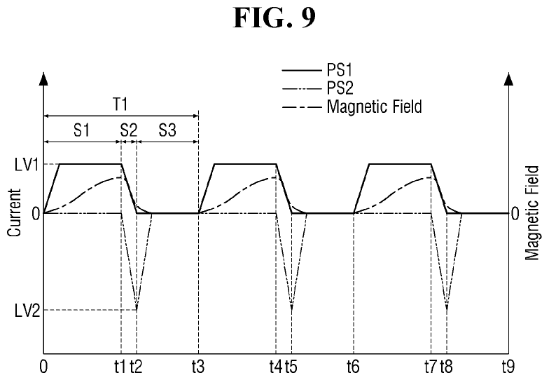

FIG. 9 is a timing view illustrating a pulse current of the plasma processing apparatus of FIG. 7. In FIG. 9, a solid line represents the current applied to the first sub-coil 140a in accordance with the first DC pulse signal PS1, a two-point dashed line represents the current applied to the second sub-coil 140b in accordance with the second DC pulse signal PS2, and a dotted dashed line represents a magnetic field generated by the electromagnet 140 in accordance with the first DC pulse signal PS1 and the second DC pulse signal PS2.

Referring to FIGS. 7 to 9, each of the first DC pulse signal PS1 and the second DC pulse signal PS2 may include a first section S1, a second section S2, and a third section S3.

At the first section S1, the first DC pulse signal PS1 may be provided at the first level LV1 having the first polarity (e.g., +). For example, the first DC pulse signal PS1 may be provided in the first direction D1 (e.g., clockwise direction in FIG. 8). Therefore, as shown in FIG. 9, the current applied to the first sub-coil 140a at the first section S1 (e.g., 0 to t1, t3 to t4 or t6 to t7) may reach the first level LV1. The first section S1 of the second DC pulse signal PS2 may be an ‘OFF’ section. Therefore, the magnetic field may be generated from the electromagnet 140 in a predetermined direction (e.g., in a direction toward the plasma P or away from the plasma P).

At the second section S2, the second DC pulse signal PS2 may be provided at the second level LV2 having the second polarity (e.g., −). For example, the second DC pulse signal PS2 may be provided in the second direction D2 (e.g., the counterclockwise direction in FIG. 8). Therefore, as shown in FIG. 9, the current applied to the second sub-coil 140b at the second section S2 (e.g., t1 to t2, t4 to t5 or t7 to t8) may reach the second level LV2. The second section S2 of the first DC pulse signal PS1 may be an ‘OFF’ section. Therefore, the intensity of the magnetic field generated at the first section S1 may be quickly reduced.

The third section S3 of the first DC pulse signal PS1 and the third section S3 of the second DC pulse signal PS2 may be all ‘OFF’ sections. Therefore, at the end time point (e.g., t3, t6 or t9) of each period T1, the intensity of the magnetic field generated by the electromagnet 140 may be zero (0).

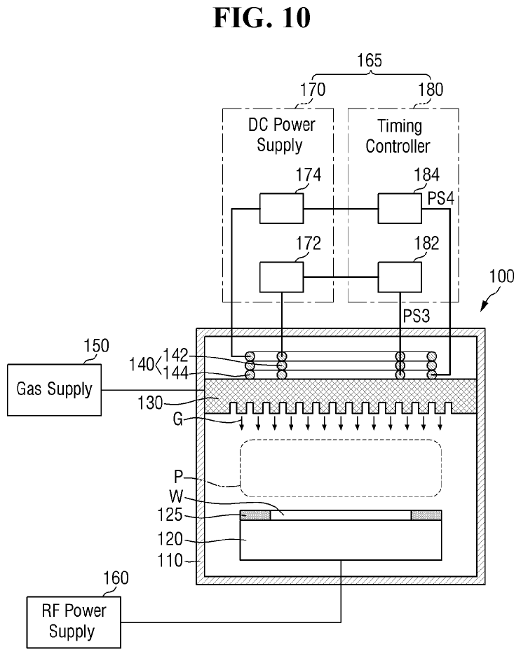

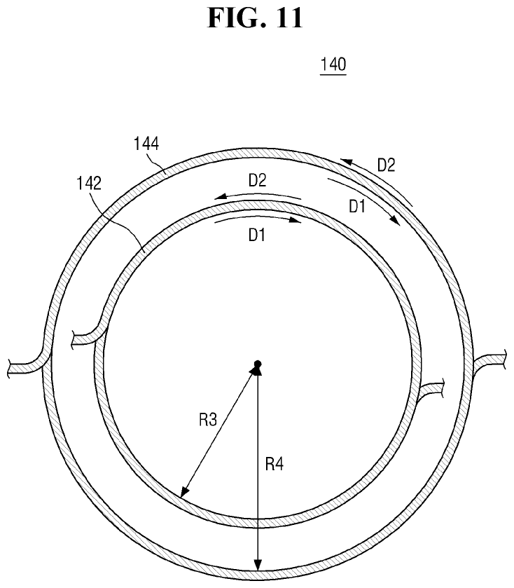

FIG. 10 illustrates a plasma processing apparatus according to one or more embodiments. FIG. 11 is a plan view illustrating an electromagnet of the plasma processing apparatus of FIG. 10. Redundant portions of those described above with reference to FIGS. 1 to 9 will be briefly described or omitted.

Referring to FIGS. 10 and 11, in the plasma processing apparatus according to one or more embodiments, the electromagnet 140 may include a first coil 142, and a second coil 144.

Each of the first coil 142 and the second coil 144 may generate a magnetic field when a current flows. The magnetic field generated by the first coil 142 and the second coil 144 may be applied to the plasma P to control distribution of the plasma P. Each of the first coil 142 and the second coil 144 may include solenoid, but is not limited thereto.

As shown in FIG. 11, the first coil 142 may have a third radius R3, and the second coil 144 may have a fourth radius R4 different from the third radius R3. For example, the fourth radius R4 of the second coil 144 may be greater than the third radius R3 of the first coil 142. In one or more embodiments, the first coil 142 and the second coil 144 may share the same central axis.

In one or more embodiments, the difference between the third radius R3 and the fourth radius R4 may be about 10% or more with respect to the third radius R3. In this case, the first coil 142 and the second coil 144 may control distribution of the plasma P in different areas.

The pulse current generator 165 may be connected to the first coil 142 and the second coil 144, respectively. For example, the DC power supply 170 may include a third sub-DC power source 172 and a fourth sub-DC power source 174. The timing controller 180 may include a third sub-timing controller 182 (connected to the third sub-DC power source 172) and a fourth sub-timing controller 184 (connected to the fourth sub-DC power source 174).

The third sub-timing controller 182 may convert a third DC signal provided from the third sub-DC power source 172 into a third DC pulse signal PS3. In addition, the third sub-DC power source 172 and the third sub-timing controller 182 may form a closed circuit with the first coil 142. Therefore, the third DC pulse signal PS3 may be provided to the first coil 142.

The fourth sub-timing controller 184 may convert a fourth DC signal provided from the fourth sub-DC power source 174 into a fourth DC pulse signal PS4. In addition, the fourth sub-DC power source 174 and the fourth sub-timing controller 184 may form a closed circuit with the second coil 144. Therefore, the fourth DC pulse signal PS4 may be provided to the second coil 144.

In one or more embodiments, a frequency of the third DC pulse signal PS3 and a frequency of the fourth DC pulse signal PS4 may be 100 Hz or higher. In one or more embodiments, the frequency of the third DC pulse signal PS3 and the frequency of the fourth DC pulse signal PS4 may be 1 kHz or higher.

In one or more embodiments, the pulse current generator 165 may respectively control the third DC pulse signal PS3 and the fourth DC pulse signal PS4 to independently flow along the electromagnet 140. For example, as shown in FIG. 11, the third DC pulse signal PS3 may be controlled to flow in the first direction D1 or the second direction D2 along the first coil 142, and the fourth DC pulse signal PS4 may be controlled to flow in the first direction D1 or the second direction D2 along the second coil 144.

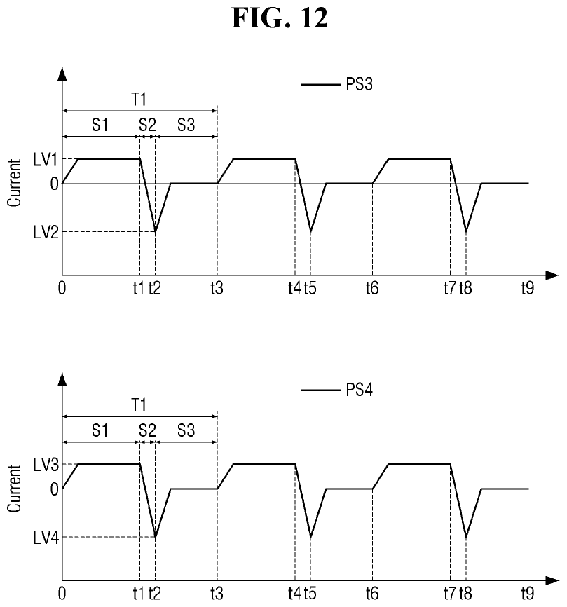

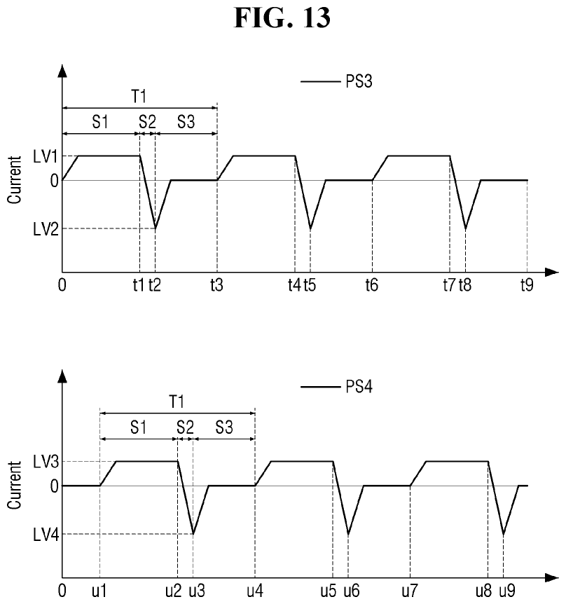

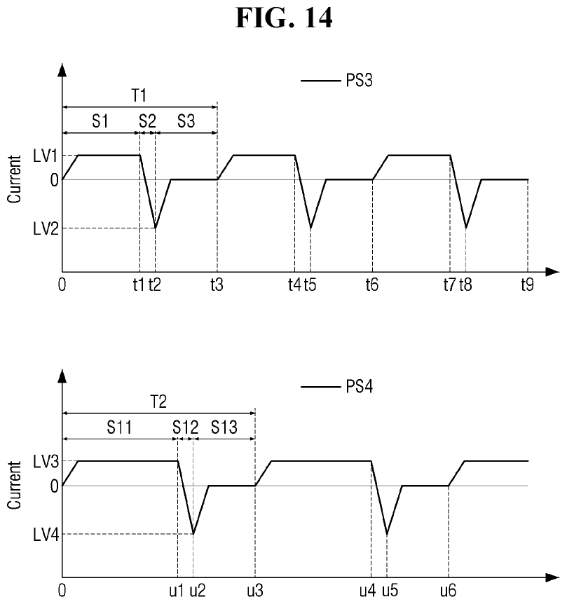

FIGS. 12 to 14 are various timing views illustrating a pulse current of the plasma processing apparatus of FIG. 10. In FIGS. 12 to 14, a solid line of an upper graph represents the current applied to the first coil 142 in accordance with the third DC pulse signal PS3, and a solid line of a lower graph represents the current applied to the second coil 144 in accordance with the fourth DC pulse signal PS4.

Referring to FIGS. 10 to 12, each of the third DC pulse signal PS3 and the fourth DC pulse signal PS4 may include a first section S1, a second section S2, and a third section S3.

At the first section S1, the third DC pulse signal PS3 may be provided at the first level LV1 having the first polarity (e.g., +), and the fourth DC pulse signal PS4 may be provided at the third level LV3 having the first polarity (e.g., +). For example, both the third DC pulse signal PS3 and the fourth DC pulse signal PS4 may be provided in the first direction D1 (e.g., clockwise direction in FIG. 11). A magnitude of the third level LV3 is shown as being the same as that of the first level LV1, but this is only exemplary, and the magnitude of the third level LV3 may be smaller than or equal to that of the first level LV1.

At the second section S2, the third DC pulse signal PS3 may be provided at the second level LV2 having the second polarity (e.g.,-), and the fourth DC pulse signal PS4 may be provided at the fourth level LV4 having the second polarity (e.g., −). For example, both the third DC pulse signal PS3 and the fourth DC pulse signal PS4 may be provided in the second direction D2 (e.g., counterclockwise direction in FIG. 11). The magnitude of the fourth level LV4 is the same as that of the second level LV2, but this is only exemplary, and the magnitude of the fourth level LV4 may be smaller than or equal to that of the second level LV2.

The third section S3 of the third DC pulse signal PS3 and the third section S3 of the fourth DC pulse signal PS4 may be all ‘OFF’ sections.

Referring to FIGS. 10, 11 and 13, the third DC pulse signal PS3 and the fourth DC pulse signal PS4 may have their respective phases different from each other.

For example, the start time point (e.g., 0, t3, or t6) of the first section S1 of the third DC pulse signal PS3 may be different from a start time point (e.g., u1, u4, or u7) of the first section S1 of the fourth DC pulse signal PS4. In addition, the start time point (e.g., t1, t4, or t7) of the second section S2 of the third DC pulse signal PS3 may be different from a start time point (e.g., u2, u5 or u8) of the second section S2 of the fourth DC pulse signal PS4. In addition, the start time point (e.g., t2, t5, or t8) of the third section S3 of the third DC pulse signal PS3 may be different from a start time point (e.g., u3, u6, or u9) of the second section S2 of the fourth DC pulse signal PS4.

Referring to FIGS. 10, 11 and 14, the third DC pulse signal PS3 and the fourth DC pulse signal PS4 may have their respective periods different from each other.

For example, the third DC pulse signal PS3 may include a first section S1, a second section S2 and a third section S3, and the fourth DC pulse signal PS4 may include a fifth section S11, a sixth section S12 and a seventh section S13.

At the fifth section S11, the fourth DC pulse signal PS4 may be provided at the third level LV3 having the first polarity (e.g., +). At the sixth section S12, the fourth DC pulse signal PS4 may be provided at the fourth level LV4 having the second polarity (e.g., −). The seventh section S13 of the fourth DC pulse signal PS4 may be an ‘OFF’ section.

A period T2 of the fourth DC pulse signal PS4 (, which includes the fifth section S11, the sixth section S12 and the seventh section S13,) may be different from the period T1 of the third DC pulse signal PS3 (, which includes the first section S1, the second section S2 and the third section S3). For example, a length of the fifth section S11 may be different from that of the first section S1. A length of the sixth section S12 is shown as being the same as that of the second section S2, but this is only exemplary, and the length of the sixth section S12 may be different from that of the second section S2. In addition, a length of the seventh section S13 is shown as being the same as that of the third section S3, but this is only exemplary, and the length of the seventh section S13 may be different from that of the third section S3.

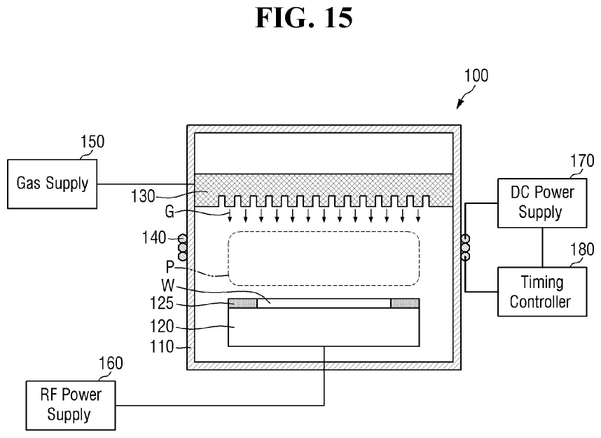

FIGS. 15 to 17 illustrate a plasma processing apparatus according to one or more embodiments. Redundant portions of those described above with reference to FIGS. 1 to 14 will be briefly described or omitted.

Referring to FIG. 15, in the plasma processing apparatus according to one or more embodiments, the electromagnet 140 may apply a magnetic field to the plasma P at a lateral direction of the plasma P.

For example, the electromagnet 140 may be disposed on the side of the chamber body 110, as shown in FIG. 15. The electromagnet 140 is shown as being disposed outside the chamber body 110, but this is only exemplary, and the electromagnet 140 may be disposed inside the chamber body 110.

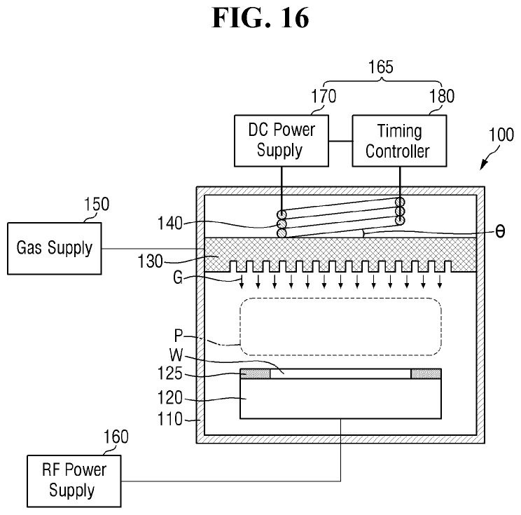

Referring to FIG. 16, in the plasma processing apparatus according to one or more embodiments, the electromagnet 140 may be disposed to be inclined.

For example, a lower surface of the electromagnet 140 may be inclined at a predetermined angle 0 with the upper surface of the distribution plate 130. The electromagnet 140 may control distribution of the plasma P by applying the magnetic field obliquely above the plasma P. For example, the electromagnet 140 may be used to control distribution of the plasma P that is asymmetrically formed.

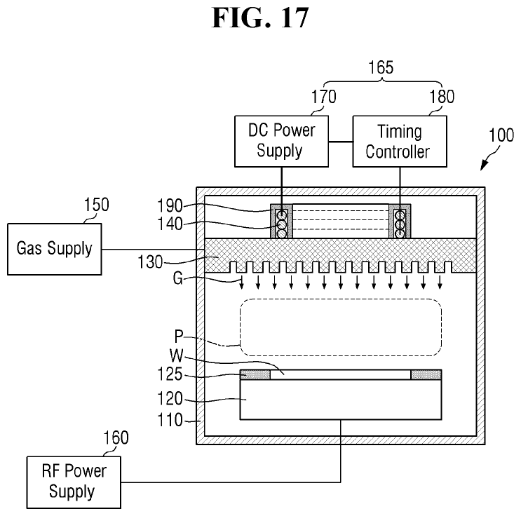

Referring to FIG. 17, the plasma processing apparatus according to one or more embodiments may further include a magnetic field shielding enclosure 190.

The magnetic field shielding enclosure 190 may surround a portion of the electromagnet 140. For example, the magnetic field shielding enclosure 190 may be provided in a ring shape to surround a portion of the electromagnet 140. Further, the magnetic field shielding enclosure 190 may expose another portion of the electromagnet 140 directed toward the plasma P. For example, when the electromagnet 140 is disposed above the plasma P, the magnetic field shielding enclosure 190 may expose the lower surface of the electromagnet 140, and may cover an inner side, an outer side and an upper surface of the electromagnet 140.

The magnetic field shielding enclosure 190 may further improve a control capability for the distribution of the plasma P by concentrating the magnetic field generated by electromagnet 140 toward the plasma P. The magnetic field shielding enclosure 190 may include, but is not limited to, iron (Fe), nickel (Ni), cobalt (Co) or permalloy, which has high permeability.

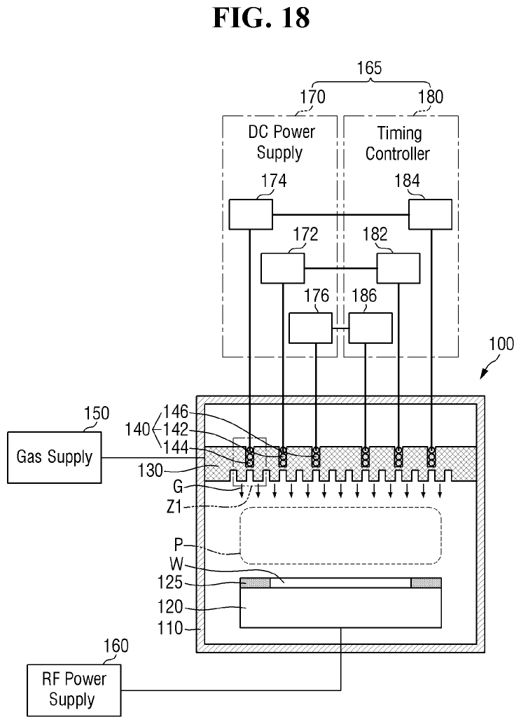

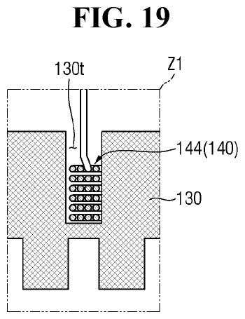

FIG. 18 illustrates a plasma processing apparatus according to one or more embodiments. FIG. 19 is an enlarged view illustrating an area Z1 of FIG. 18. Redundant portions of those described above with reference to FIGS. 1 to 17 will be briefly described or omitted.

Referring to FIGS. 18 and 19, in the plasma processing apparatus according to one or more embodiments, the electromagnet 140 may be disposed in the distribution plate 130.

For example, as shown in FIG. 19, the distribution plate 130 may include a trench 130t downward extended from the upper surface of the distribution plate 130. The electromagnet 140 may be disposed in the trench 130t. For example, the trench 130t may be provided in a ring shape to accommodate the electromagnet 140 of a coil shape.

As the frequency of the pulse current applied to the electromagnet 140 is increased, a problem may occur in that so-called eddy effect (eddy current) is generated in a conductor area (for example, in the distribution plate 130 interposed between the plasma P and the electromagnet 140) disposed around the electromagnet 140. The plasma processing apparatus according to one or more embodiments may minimize the eddy effect (the eddy current) by disposing the electromagnet 140 in the distribution plate 130. In detail, as described above, as the electromagnet 140 is disposed in the trench 130t of the distribution plate 130, the conductor area interposed between the electromagnet 140 and the plasma P may be minimized. Therefore, the plasma processing apparatus may be provided to avoid performance degradation caused by the eddy effect (the eddy current).

In one or more embodiments, the electromagnet 140 may include a plurality of coils 142, 144 and 146, for example, as shown in FIG. 18.

Each of the plurality of coils 142, 144 and 146 may generate a magnetic field when a current flows. The magnetic field generated by each of the coils 142, 144 and 146 may be applied to the plasma P to control distribution of the plasma P. Each of the coils 142, 144 and 146 may include solenoid, but is not limited thereto.

In one or more embodiments, the coils 142, 144 and 146 may control distribution of the plasma P in different areas. For example, a difference in radiuses among the coils 142, 144 and 146 may be about 10% or more.

Each of the coils 142, 144 and 146 is shown as being a single coil, but this is only exemplary. In one or more embodiments, each of the coils 142, 144 and 146 may include two or more sub-coils (e.g., the first sub-coil 140a and the second sub-coil 140b of FIGS. 7 and 8).

The pulse current generator 165 may be connected with the respective coils 142, 144 and 146. For example, the DC power supply 170 may include a plurality of sub-DC power sources 172, 174 and 176, and the timing controller 180 may include a plurality of sub-timing controllers 182, 184 and 186.

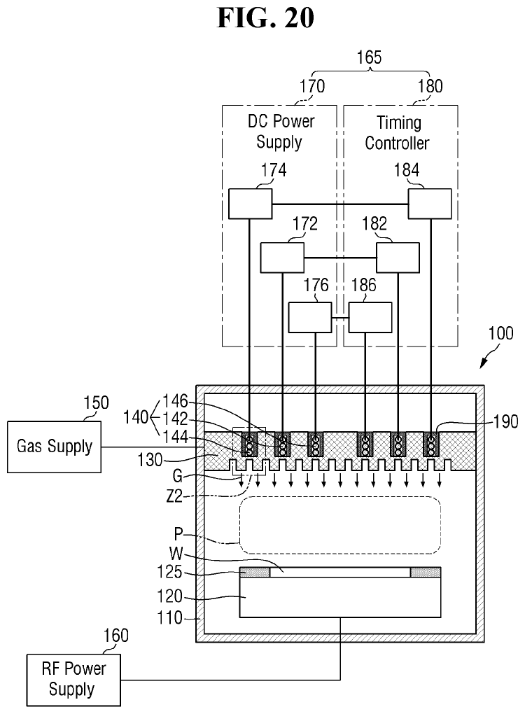

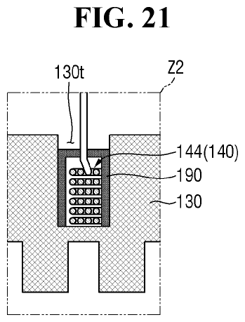

FIG. 20 illustrates a plasma processing apparatus according to one or more embodiments. FIG. 21 is an enlarged view illustrating an area Z2 of FIG. 20. Redundant portions of those described above with reference to FIGS. 1 to 19 will be briefly described or omitted.

Referring to FIGS. 20 and 21, the plasma processing apparatus according to one or more embodiments may further include a magnetic field shielding enclosure 190.

The magnetic field shielding enclosure 190 may be disposed in the trench 130t of distribution plate 130. The magnetic field shielding enclosure 190 may expose the lower surface of the electromagnet 140 disposed in the trench 130t, and may cover the inner side, the outer side and the upper surface of the electromagnet 140. Since the magnetic field shielding enclosure 190 is similar to that described above with reference to FIG. 17 except that the magnetic field shielding enclosure 190 is disposed in the trench 130t, its detailed description will be omitted.

Hereinafter, a method for fabricating a semiconductor device according to exemplary embodiments will be described with reference to FIGS. 1 to 23.

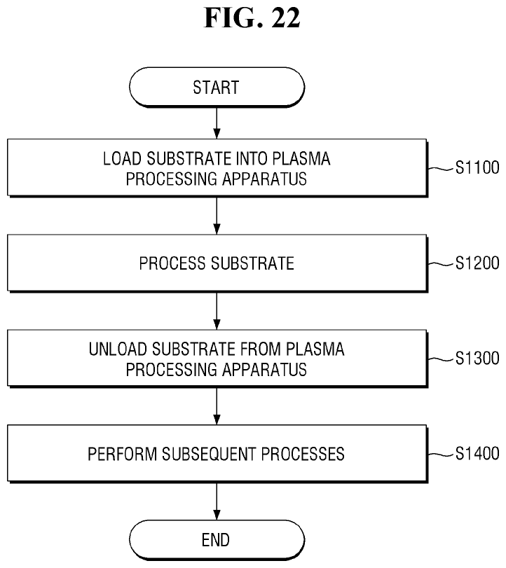

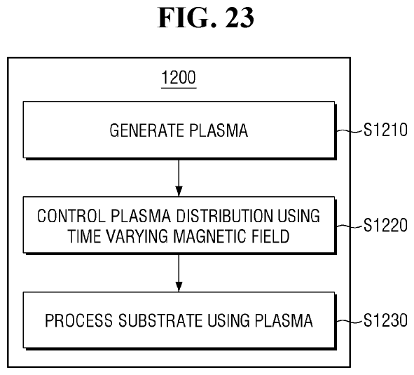

FIGS. 22 and 23 are flow charts illustrating a method for fabricating a semiconductor device according to one or more embodiments.

Referring to FIGS. 1, 22 and 23, first of all, the substrate W is loaded into the plasma processing apparatus (S1100). The substrate W may include, for example, silicon (Si). The substrate W may include a semiconductor element such as germanium (Ge) or a compound semiconductor such as silicon carbide (SiC), gallium arsenide (GaAs), indium arsenide (InAs) and indium phosphide (InP). In one or more embodiments, the substrate W may include a conductive area, for example, a well doped with impurities. The substrate W may have a first surface, which is an active surface, and a second surface, which is an inactive surface opposite to the first surface. The substrate W may be disposed on the stage 120 such that the second surface faces the stage 120.

The substrate W may be a wafer on which a series of processes are performed. The series of processes that may be performed on the substrate W may include i) an oxidation process for forming an oxide film, ii) a lithography process including spin coating, exposure and development, iii) a thin film deposition process, iv) a dry or wet etching process and/or v) a metal wiring process.

The oxidation process is a process for forming a thin and uniform silicon oxide film by chemically reacting oxygen or vapor with a surface of a silicon substrate at a high temperature of 800° C. to 1200° C. The oxidation process may include dry oxidation and wet oxidation. In the dry oxidation, the oxide film may be formed by reacting with oxygen gas, and in the wet oxidation, the oxide film may be formed by reacting oxygen with vapor.

In one or more embodiments, a silicon on insulator (SOI) structure may be formed on the substrate W by the oxidation process. The substrate W may include a buried oxide layer. In one or more embodiments, the substrate may have various device isolation structures such as shallow trench isolation (STI).

The lithography process is a process of transferring a circuit pattern, which has been previously formed on a lithography mask, to the substrate W through exposure. The lithography process may be performed in the order of spin coating, exposure and developing processes.

The thin film deposition process may be any one of, for example, atomic layer deposition (ALD), chemical vapor deposition (CVD), plasma-enhanced CVD (PECVD), metal organic CVD (MOCVD), physical vapor deposition (PVD), reactive pulsed laser deposition, molecular beam epitaxy, and DC magnetron sputtering.

The dry etching process may be any one of reactive ion etching (RIE), deep RIE (DRIE), ion beam etching (IBE) and Ar milling. As another example, the dry etching process, which may be performed on the substrate W, may be atomic layer etching (ALE). In addition, the wet etching process, which may be performed on the substrate W, may be an etching process using at least one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂ or COS as an etchant gas.

The metal wiring process may be a process of forming a conductive wiring (metal wiring) to implement a circuit pattern for the operation of a semiconductor device. Transfer paths of a ground, a power and a signal, which are for operating the semiconductor devices, may be formed by the metal wiring process. The metal wiring may include gold, platinum, silver, aluminum, tungsten or the like.

In one or more embodiments, a planarization process such as a chemical mechanical polish (CMP) process, an ion implantation process or the like may be performed.

The substrate W may be transported by a transport device that includes a refined clean room transport system. The transport device may include a conveyor system or the like. The transport device may load the substrate W into the above-described plasma processing apparatus. In some cases, the transport device may load the substrate W into a load port adjacent to the above-described plasma processing apparatus, and the substrate W may be loaded into the aforementioned plasma processing apparatus from the load port by a separate robot arm.

Next, the substrate W is processed (S1200). The processing of the substrate W may be performed by the plasma processing apparatus described above with reference to FIGS. 1 to 21.

For example, the plasma P may be generated in the plasma chamber 100 by using the gas supply 150 and the RF power supply 160 (S1210). Subsequently, a time varying magnetic field may be generated using the electromagnet 140 and the pulse current generator 165, and distribution of the plasma P may be controlled using the time varying magnetic field (S1220). Subsequently, the substrate W may be processed using the plasma P of which distribution is controlled (S1230). The process of processing the substrate W may include various processes, for example, an etching process, a deposition process, an ashing process, a cleaning process and the like, but is not limited thereto.

Then, the substrate W is unloaded from the plasma processing apparatus (S1300). The substrate W may be transported by, for example, the transport device.

Afterwards, a subsequent process is performed (S1400).

For example, the unloaded substrate W may be input to a facility for the subsequent process. The subsequent process may include the oxidation process, the lithography process, the thin film deposition process, the dry or wet etching process and/or the metal wiring process, and may include an electrical die sorting (EDS) process, a packaging process and a package test process.

The EDS process may refer to a process for applying an electrical signal to the semiconductor devices formed on the substrate W and determining whether the semiconductor devices are defective by a signal output from the semiconductor devices in response to the applied electrical signal.

The packaging process may include a wafer back grinding process, a wafer sawing process, a die attach process, a wire bonding process, a molding process, a marking process, a solder ball mount process, and a singulation (also known as dicing) process.

The package test process may include an assembly out, a DC test, a burn-in test, a monitoring burn-in test, a post burn-in test, and a final test.

While certain example embodiments of the disclosure have been particularly shown and described, it will be understood by those of ordinary skill in the art that various changes in form and details may be made therein without departing from the spirit and scope of the disclosure as defined by the following claims.

1. A plasma processing apparatus comprising:
a plasma chamber;
a radio frequency (RF) power supply configured to generate plasma in the plasma chamber;
an electromagnet configured to apply a magnetic field to the plasma; and
a pulse current generator configured to provide a pulse current to the electromagnet,
wherein each period of the pulse current comprises a first section and a second section subsequent to the first section, and
wherein the pulse current generator is further configured to:
provide, at the first section, the pulse current to the electromagnet in a first direction to generate the magnetic field, and
provide, at the second section, the pulse current to the electromagnet in a second direction opposite to the first direction to reduce intensity of the magnetic field generated at the first section.

2. The plasma processing apparatus of claim 1, wherein a frequency of the pulse current is at least 100 Hz.

3. The plasma processing apparatus of claim 1, wherein each period of the pulse current further comprises a third section subsequent to the second section, and
wherein the third section is an off-section.

4. The plasma processing apparatus of claim 1, wherein the pulse current comprises a direct current (DC) pulse signal, and
wherein the pulse current generator is further configured to:
provide, at the first section, the DC pulse signal at a first level having a first polarity, and
provide, at the second section, the DC pulse signal at a second level having a second polarity opposite to the first polarity.

5. The plasma processing apparatus of claim 1, wherein the electromagnet comprises a first coil having a first radius and a second coil having a second radius different from the first radius, and
wherein the pulse current comprises a first direct current (DC) pulse signal provided to the first coil and a second DC pulse signal provided to the second coil.

6. The plasma processing apparatus of claim 5, wherein a difference between the first radius and the second radius is at least 10% of the first radius.

7. (canceled)

8. (canceled)

9. The plasma processing apparatus of claim 1, wherein the electromagnet comprises a first sub-coil having a first radius and a second sub-coil having a second radius different from the first radius,
wherein the pulse current comprises a first DC pulse signal provided to the first sub-coil and a second DC pulse signal provided to the second sub-coil,
wherein the first DC pulse signal has the first direction at the first section, and
wherein the second DC pulse signal has the second direction at the second section.

10. The plasma processing apparatus of claim 9, wherein a difference between the first radius and the second radius is at least 10% of the first radius.

11. A plasma processing apparatus comprising:
a plasma chamber;
an radio frequency (RF) power supply configured to generate plasma in the plasma chamber;
an electromagnet configured to apply a magnetic field to the plasma; and
a pulse current generator configured to provide a direct current (DC) pulse signal to the electromagnet,
wherein each period of the DC pulse signal comprises a first section and a second section subsequent to the first section, and
wherein the pulse current generator is further configured to:
provide, at the first section, the DC pulse signal at a first level having a first polarity, and
provide, at the second section, the DC pulse signal at a second level having a second polarity opposite to the first polarity.

12. The plasma processing apparatus of claim 11, wherein a frequency of the DC pulse signal is at least 100 Hz.

13. The plasma processing apparatus of claim 11, wherein the second section is shorter than the first section.

14. The plasma processing apparatus of claim 13, wherein a second length of the second section is 25% or less of a first length of the first section.

15. The plasma processing apparatus of claim 11, wherein a second magnitude of the second level is greater than a first magnitude of the first level.

16. The plasma processing apparatus of claim 15, wherein the second magnitude of the second level is at least twice or more of the first magnitude of the first level.

17. (canceled)

18. The plasma processing apparatus of claim 11, wherein each period of the DC pulse signal further comprises a third section preceding the first section,
wherein the pulse current generator is further configured to provide, at the third section, the DC pulse signal at a third level having the first polarity, and
wherein the third level is greater than the first level.

19. The plasma processing apparatus of claim 11, wherein the pulse current generator comprises a direct current (DC) power supply configured to provide a DC signal, and a timing controller configured to generate the DC pulse signal from the DC signal.

20. A plasma processing apparatus comprising:
a chamber body;
a stage, on which a substrate is mounted, in the chamber body;
a distribution plate spraying a process gas into the chamber body;
a radio frequency (RF) power supply configured to generate plasma from the process gas;
a direct current (DC) power supply configured to provide a DC signal;
a timing controller configured to generate a DC pulse signal from the DC signal; and
an electromagnet in the distribution plate, the electromagnet being configured to generate a magnetic field by using the DC pulse signal,
wherein each period of the DC pulse signal comprises a first section and a second section subsequent to the first section,
wherein, at the first section, the DC pulse signal is provided at a first level having a first polarity, and
wherein, at the second section, the DC pulse signal is provided at a second level having a second polarity opposite to the first polarity.

21. The plasma processing apparatus of claim 20, wherein a frequency of the DC pulse signal is 100 Hz or higher.

22. The plasma processing apparatus of claim 20, wherein the distribution plate comprises a trench extended from an upper surface of the distribution plate, and
wherein the electromagnet is disposed in the trench.

23. The plasma processing apparatus of claim 22, further comprising a magnetic field shielding enclosure in the trench, the magnetic field shielding enclosure exposing a lower surface of the electromagnet.

24. (canceled)

25. (canceled)

26. (canceled)

27. (canceled)

28. (canceled)

29. (canceled)
